(19) United States
(12) Patent Application Publication
(10) Pub. No.: US 2009/0211790 A1
(43) Pub. Date: Aug. 27, 2009

(54) Connecting structure and connecting method, liquid ejection head and method of manufacturing same

(75) Inventor: Tsutomu Yokouchi, Kanagawa-ken (JP)

Correspondence Address: AKERMAN SENTERFITT, 8100 BOONE BOULEVARD, SUITE 700, VIENNA, VA, 22182-2683, US

(73) Assignee: FUJIFILM Corporation, Tokyo (JP)

(21) Appl. No.: 12/379,518

(22) Filed: Feb. 24, 2009

(30) Foreign Application Priority Data
Feb. 25, 2008 (JP) 2008-043115

(51) Int. Cl. H05K 1/00; H05K 3/30; B41J 2/14

(52) U.S. Cl. 174/254; 29/837; 347/50

(57) ABSTRACT

The connecting structure of a flexible circuit board and electronic components, includes: the flexible circuit board having: a pattern of wires, holes passing through the flexible circuit board in a thickness direction of the wires at parts of the wires to which the electronic components are connected, and a weakened part arranged on a bending line in a bending part of the flexible circuit board on which the flexible circuit board bends when the wires are connected with the electronic components; and the electronic components respectively having projections on parts to which the wires are connected, wherein the wires are electrically connected with the electronic components in a state where the projections are inserted in the holes and the flexible circuit board bends on the weakened part.

### BACKGROUND OF THE INVENTION

1. Field of the Invention

The present invention relates to a connecting structure and connecting method, and a liquid ejection head and a method of manufacturing same, and more particularly to electrical connection technology which is suitable for connecting piezoelectric elements with wires on a flexible circuit board, and the like, and to a liquid ejection head which uses this technology and a method of manufacturing such a liquid ejection head.

2. Description of the Related Art

From the viewpoint of improving the production yield in connecting a flexible circuit board with another circuit board, Japanese Patent Application Publication No. 2007-036009 discloses a structure in which through holes are formed in the wiring on the flexible circuit board, projections are provided in the other circuit board to be connected, and the projections on the other circuit board to be connected are inserted into the through holes in the flexible circuit board, whereupon electrical connections are made by spreading out (by pressing) the tip portions of the projections. A connecting structure of this kind has merits in that it is able to achieve reliable electrical connections, and furthermore a heating and pressing bonding step is not required. However, this structure does not achieve the control of the position where the flexible circuit board bends and therefore positional alignment is difficult. Furthermore, a stress is applied to the connecting parts due to the force of the bent substrate of the flexible circuit board seeking to revert to its original position and hence there is a problem in that the connection becomes broken.

### SUMMARY OF THE INVENTION

The present invention has been contrived in view of these circumstances, an object thereof being to provide a connecting structure and a connecting method for a flexible circuit board, and a liquid ejection head using same and a method of manufacturing such a head, whereby more reliable electrical connections can be achieved by simplifying positional alignment and preventing detachment after connection.

In order to attain the aforementioned object, the present invention is directed to a connecting structure of a flexible circuit board and electronic components, comprising: the flexible circuit board having: a pattern of wires, holes passing through the flexible circuit board in a thickness direction of the wires at parts of the wires to which the electronic components are connected, and a weakened part arranged on a bending line in a bending part of the flexible circuit board on which the flexible circuit board bends when the wires are connected with the electronic components; and the electronic components respectively having projections on parts to which the wires are connected, wherein the wires are electrically connected with the electronic components in a state where the projections are inserted in the holes and the flexible circuit board bends on the weakened part.

In order to attain the aforementioned object, the present invention is also directed to a method of connecting electronic components and a flexible circuit board having a pattern of wires, the method comprising the steps of: forming holes passing through the flexible circuit board in a thickness direction of the wires at parts of the wires to which the electronic components are connected; forming a weakened part arranged on a bending line in a bending part of the flexible circuit board on which the flexible circuit board bends when the wires are connected with the electronic components; forming projections on parts of the electronic components to which the wires are connected; and connecting the electronic components and the flexible circuit board by inserting the projections into the holes to electrically connect the wires with the electronic components and bending the flexible circuit board on the weakened part.

According to the present invention, the flexible circuit board can readily bend on a prescribed part due to the weakened part, which may have a series of perforations or a groove, formed in the bending part of the flexible circuit board, positional alignment during connection can be achieved readily, and the stress applied to the connections can be reduced. Thereby, it is possible to achieve reliable electrical connections which are not liable to become broken.

### BRIEF DESCRIPTION OF THE DRAWINGS

The nature of this invention, as well as other objects and advantages thereof, will be explained in the following with reference to the accompanying drawings, in which like reference characters designate the same or similar parts throughout the figures and wherein:

FIG. 1 is a cross-sectional diagram of a liquid droplet ejection head according to an embodiment of the present invention;

FIG. 2 is a principal plan view of a flexible circuit board as viewed from the lower side;

FIG. 3 is a perspective diagram showing the connecting structure of the flexible circuit board and piezoelectric elements;

FIG. 4 is an enlarged diagram of a connecting part;

FIG. 5 is a diagram showing a portion of a manufacturing process for the liquid droplet ejection head;

FIG. 6 is a diagram showing a fixing method using fixing resin; and

FIG. 7 is a perspective diagram showing a further embodiment of the present invention.

### DETAILED DESCRIPTION OF THE PREFERRED EMBODIMENTS

### First Embodiment

### Structure of Liquid Ejection Head

The structure of the liquid ejection head according to an embodiment of the present invention is hereby described. The description given here relates to the mode of a flexible circuit board and a connecting structure for same according to an embodiment of the present invention, while utilizing the head structure disclosed in Japanese Patent Application Publication No. 2007-036009.

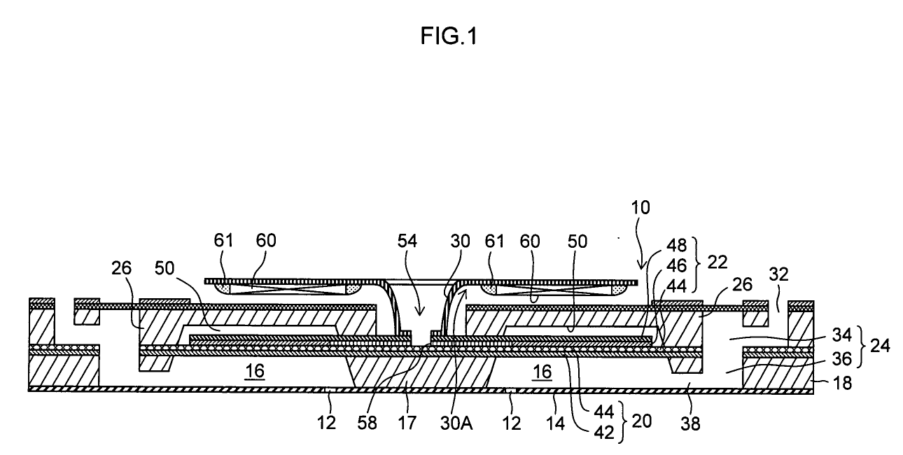

FIG. 1 is a cross-sectional diagram of a liquid ejection head 10. The liquid ejection head 10 includes: a nozzle plate 14 having nozzle openings 12; a pressure chamber forming plate 18, which is bonded to the upper surface of the nozzle plate 14 and forms partitions 17 defining pressure chambers 16; a diaphragm 20, which is bonded to the upper surface of the pressure chamber forming plate 18; piezoelectric elements 22, which are bonded to the upper surface of the diaphragm 20; a reservoir forming plate 26, which forms a reservoir 24 as well as covering the upper side of the piezoelectric elements 22 while ensuring a space (displacement space) above the piezoelectric elements 22; and a flexible circuit board 30, which has electrical connections with the piezoelectric elements 22.

The pressure chambers 16 are formed correspondingly to the nozzle openings 12. Each of the pressure chambers 16 is formed as a space defined by the nozzle plate 14, the diaphragm 20, and the partitions 17 constituted of the pressure chamber forming plate 18.

The reservoir 24 is a liquid chamber for temporarily holding (storing) liquid that has entered through a liquid introduction port 32, which is connected to a liquid tank (not shown). The liquid is supplied from the reservoir 24 to the respective pressure chambers 16. In other words, the reservoir 24 forms a common liquid holding chamber (also referred to as a common liquid chamber) for the pressure chambers 16.

A connection part 36 and an individual supply channel 38 are formed in the pressure chamber forming plate 18. The connection part 36 is connected to a reservoir part 34 formed in the reservoir forming plate 26, and the liquid supplied from the reservoir 24 through the connection part 36 is supplied to each of the pressure chambers 16 through the individual supply channel 38.

The diaphragm 20 covers the upper surface of the pressure chamber forming plate 18, and is constituted of an elastic film 42 adjacent to the pressure chamber 16, and an lower electrode film 44 arranged on the upper surface of the elastic film 42. The lower electrode film 44 functions as a common electrode for the plurality of piezoelectric elements 22, which correspond to the respective pressure chambers 16. In the present embodiment, the diaphragm 20 has the structure in which the lower electrode film 44 is arranged on the elastic film 42; however, instead of this composition, it is also possible to adopt a structure that omits the elastic film 42 by using a diaphragm made of metal, for instance, and thus using the diaphragm to serve also as the common electrode.

The piezoelectric element 22 includes a piezoelectric film 46, which is arranged on the upper surface of the lower electrode film 44, and an upper electrode film 48, which is arranged on the upper surface of the piezoelectric film 46. In other words, the piezoelectric element 22 is constituted of the lower electrode film 44, the upper electrode film 48, and the piezoelectric film 46 interposed between the two electrode films 44 and 48. The piezoelectric element 22 is provided for each pressure chamber 16, and the upper electrode film 48 functions as an individual electrode for each piezoelectric element 22.

A piezoelectric element holding part 50 is provided in the region of the reservoir forming plate 26 corresponding to each piezoelectric element 22. The piezoelectric element holding part 50 ensures a space that prevents obstruction of the movement of the piezoelectric element 22, and is able to seal the space. In this way, the reservoir forming plate 26 functions as a sealing member that shuts off the piezoelectric element 22 from the external environment and seals the piezoelectric element 22.

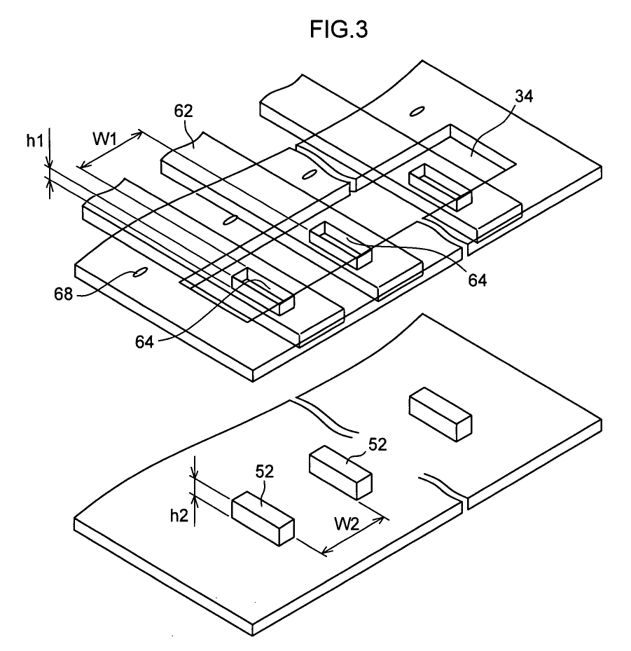

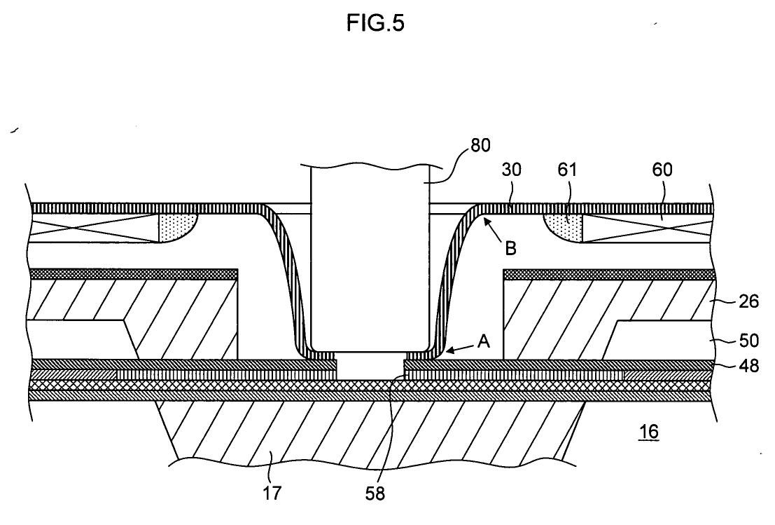

One end portion of the upper electrode film 48 of the piezoelectric element 22, which is sealed in the piezoelectric element holding part 50, extends until the outer side of the piezoelectric element holding part 50 and forms a connection terminal (electrode extending part) to make a wire connection with the flexible circuit board 30. A projection 52, which is described hereinafter with reference to FIG. 3, is formed on this connection terminal. The connection terminal having the projection 52 is arranged in the bottom of a recess or groove 54, which is formed by the piezoelectric element holding part 50 of the reservoir forming plate 26 shown in FIG. 1. Hence, the flexible circuit board 30 needs to bend in accordance with the depth of the groove 54. Furthermore, if a portion of the lower electrode film 44 is exposed above the pressure chamber forming plate 18 in the groove 54, then an insulating film 58 is provided between the upper electrode film 48 and the lower electrode film 44 in order to prevent electrical connection between the upper electrode film 48 and the lower electrode film 44 (see FIG. 5).

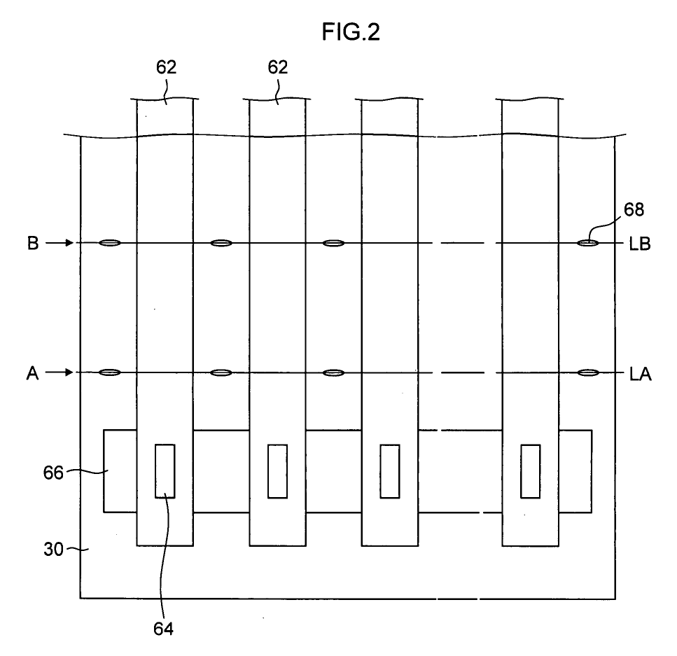

A drive circuit part 60 for driving the piezoelectric elements 22 is constituted of a circuit board or a semiconductor integrated circuit (IC) including a drive circuit, and is arranged on the lower surface 30A of the flexible circuit board 30. The drive circuit part 60 mounted on the flexible circuit board 30 is fixed with resin 61 to the flexible circuit board 30. The piezoelectric elements 22 are electrically connected with the drive circuit part 60 through wires 62 (shown in FIG. 2) of the flexible circuit board 30.

### Connecting Structure Between the Flexible Circuit Board and the Piezoelectric Elements

FIG. 2 is a plan diagram showing an enlarged view of the principal portion of the flexible circuit board 30, to which the “electronic components” or piezoelectric elements 22 are connected. FIG. 2 shows the rear side of the flexible circuit board 30, on which the wires 62 are formed (the side of the lower surface 30A in FIG. 1). The flexible circuit board 30 has elastic properties and is constituted of an insulating film member or substrate made of polyimide, for instance. The conductive wires 62 made of a conductive material such as copper are arranged by means of printing, plating, etching, or the like, on one side of the substrate of the flexible circuit board 30 (the lower surface 30A in FIG. 1).

Through holes 64 are formed at the connecting parts of the wires 62 on the flexible circuit board 30 so as to pass through in the thickness direction of the wires 62. The through holes 64 serve to secure the flexible circuit board 30 to the piezoelectric elements 22 by receiving the projections 52 (see FIG. 3) formed on the piezoelectric elements 22.

The shape of the through holes 64 is formed to be either substantially the same as the external shape of the projections 52 formed on the piezoelectric elements 22, or the through holes 64 are formed to be slightly larger than the projections 52 in such a manner that the projections 52 can be inserted readily into the through holes 64. In the present embodiment, the projections 52 are formed in an oblong rectangular shape when observed in plan view, and therefore the external shape of the through holes 64 is also formed in an oblong rectangular shape in accordance with this; however, the shape of the projections 52 and the through holes 64 is not limited to that of the present embodiment and it is also possible to adopt circular through holes in accordance with circular cylindrical projections, or the like.

Moreover, an opening 66 is formed in the connecting part of the flexible circuit board 30 so as to pass through in the thickness direction of the flexible circuit board 30. The opening 66 has an oblong rectangular shape in plan view and extends in the direction of arrangement of the wires 62. The opening 66 is provided in such a manner that the tip portions of the projections 52, which protrude from the through holes 64 when the projections 52 are inserted in the through holes 64 in the wires 62, do not make contact with the flexible circuit board 30. In other words, the opening 66 of the flexible circuit board 30 is a window that extends over the wires 62 and is formed to a size and a shape which covers the through holes 64 of the wires 62.

The through holes 64 of the wires 62 formed on the lower surface of the flexible circuit board 30 are exposed through the opening 66 formed in the flexible circuit board 30.

Furthermore, as shown in FIG. 2, a plurality of perforations 68 are formed in the flexible circuit board 30 according to the present embodiment in the bending parts of the flexible circuit board 30 (here, the two parts indicated with arrows A and B). Each perforation 68 is formed between the wires 62 on the flexible circuit board 30 (in the substrate of the flexible circuit board 30) so as to avoid the positions of the wires 62. The perforations 68 are arranged along bending lines LA and LB. Consequently, the flexible circuit board 30 has weakened parts in the bending parts in which the rigidity of the flexible circuit board 30 is reduced, and suitable bends can be achieved at the specified positions of the weakened parts.

The shape of the perforations 68 is not limited to an elliptical shape or an elongated hole that has the major axis along the bending line, and it may also be a simple circular shape. Furthermore, the perforations 68 do not necessarily have to be provided between every pair of the wires, and the shape, size, number and spacing, and the like, of the perforations 68 are designed from the viewpoint of the bending angle and the rigidity and elasticity, and the like, which are to be achieved in the flexible circuit board 30.

As shown in FIG. 3, the projections 52 are formed to correspond to the wires 62 in the connecting parts of the upper electrode film 48 of the piezoelectric elements 22 that make connection with the flexible circuit board 30. The projections 52 are made of a conductive material, such as Au, Ni, Cu, Sn, Ag, or an alloy of these.

As a method for forming the projections 52, for example a film of a conductive material made of Au, Ni, Cu, Sn, Ag or an alloy of these is deposited by electroless plating, or the like, onto the connection region of the piezoelectric elements 22. A resist is then applied onto the deposited conductive material film, and the resist is formed into a mask pattern corresponding to the projections 52. By using this resist as a mask, the unwanted portion of the conductive film is then removed by wet etching, for example, to form the projections 52 in the connection region of the piezoelectric elements 22.

In the present embodiment, the projections 52 are formed with a rectangular parallelepiped shape; however, as stated previously, the shape of the projections is not limited in particular and is designed by considering the conformity with the shape of the through holes 64 in the wires 62 arranged on the flexible circuit board 30.

The interval W1 between the through holes 64 formed in the wires 62 (i.e., the arrangement pitch of the wires 62) is set so as to be equal to the arrangement pitch W2 of the projections 52 formed on the piezoelectric elements 22. Furthermore, the thickness h2 of the projections 52 is set to be greater than the thickness h1 of the wires 62 of the flexible circuit board 30. When the projections 52 are inserted into the through holes 64 in the wires 62, the tip portions of the projections 52 protrude from the through holes 64 in the wires 62 (from the upper surface of the wires 62).

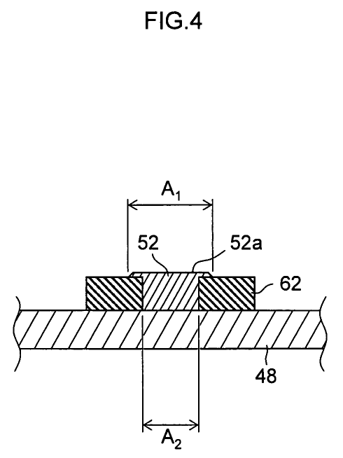

As shown in FIG. 4, the tip portion 52a of each projection 52 protruding from the through hole 64 of the wire 62 (from the upper surface of the wire 62) is pressed and spread out, and the cross-sectional area A1 of the tip portion 52a of the projection 52 is thereby made larger than the cross-sectional area A2 of the through hole 64 in the wire 62. In this way, an anchoring effect is created by the spread part of the pressed tip portion 52a of the projection 52 overlapping the upper surface of the wire 62 (the rim of the through hole 64), and due to this effect the wire 62 that has received the projection 52 cannot readily be removed, and it becomes possible to secure the piezoelectric element 22 to the flexible circuit board 30 with good mechanical reliability, as well as creating the electrical connection between the wire 62 and the upper electrode 48 of the piezoelectric element 22.

### Description of Method of Manufacture

### Step 1: Manufacture of the Head Main Portion

It is supposed that the work of bonding and assembling the other parts of the main body portion of the liquid droplet ejection head 10 shown in FIG. 1 apart from the flexible circuit board 30, in other words, the nozzle plate 14, the pressure chamber forming plate 18, the piezoelectric elements 22, the reservoir forming plate 26, and the like, have been carried out and completed in the process of manufacturing the main body of the head.

### Step 2: Manufacture of the Flexible Circuit Board

A substrate for the flexible circuit board 30 having flexibility made of polyimide, or the like, is prepared, and a film of conductive material such as copper is deposited onto the lower surface 30A of the substrate for the flexible circuit board 30. The film deposition method used may be electroless plating, electroplating, sputtering, vapor deposition, plasma CVD (chemical vapor deposition), or the like. Then, a resist (photosensitive resin) is applied onto the deposited conductive film, and the resist is formed into a mask pattern corresponding to the wires 62 and the through holes 64 formed in the wires 62. By using this resist as a mask, the unwanted portion of the conductive film is then removed by wet etching, for example, the wires 62 are formed, and the through holes 64 are formed in the connection portion of the wires 62 (see FIG. 2).

Thereupon, a mask pattern made of resist is formed on the other surface of the substrate for the flexible circuit board 30 opposite from the wires 62, and an opening 66 is formed by etching the substrate for the flexible circuit board 30 using this mask pattern as a mask.

Furthermore, rows of perforations 68 for bending are formed in the substrate for the flexible circuit board 30 by the same method as that used for the openings 66 or by a method such as laser processing, mechanical processing, or the like.

Next, the IC component of the drive circuit part 60, and the like, is installed by a flip-chip mounting on a prescribed region (mounting region) on the lower surface 30A of the flexible circuit board 30. The drive circuit part 60 is fixed on the flexible circuit board 30 with the resin 61.

### Step 3: Connection of the Flexible Circuit Board and the Piezoelectric Elements

Next, the flexible circuit board 30 is connected electrically to the upper electrode films 48 of the piezoelectric elements 22, which are arranged inside the grooves 54 of the liquid droplet ejection head 10. More concretely, firstly, the vicinity of the connecting part of the flexible circuit board 30 is bent toward the bottom of the groove 54 by using a pressing member 80 as shown in FIG. 5. In this case, it is possible to bend the flexible circuit board 30 in a straightforward and reliable fashion on the prescribed positions (indicated with the arrows A and B), since the bending parts have been processed to have the rows of perforations 68 as shown in FIG. 2.

When the flexible circuit board 30 and the upper electrode films 48 of the piezoelectric elements 22 are connected, as shown in FIGS. 3 and 4, the projections 52 formed on the upper electrode films 48 of the piezoelectric elements 22 are inserted into the through holes 64 of the wires 62 of the flexible circuit board 30, so that the projections 52 on the upper electrode films 48 fit in the through holes 64 of the wires 62. In this case, by pressing the region of the connecting part of the flexible circuit board 30 where the through holes are not formed, the through holes 64 of the wires 62 are put onto the projections 52 until reaching the base end portions of the projections 52.

Thereupon, the upper surface of each projection 52 that is protruding from the through hole 64 of the wire 62 of the flexible circuit board 30 is struck by a pressing member (which the pressing member 80 may also serve as, or which may be a separate pressing member), and the tip portion 52a of the projection 52 protruding from the through hole 64 of the wire 62 is thereby spread out (see FIG. 4). Thus, the projections 52 of the piezoelectric elements 22 are mechanically secured to the wires 62 of the flexible circuit board 30, as well as being electrically connected.

By means of the steps described above, the flexible circuit board 30 and the piezoelectric elements 22 are electrically connected.

According to the present embodiment, it is possible to bend the flexible circuit board 30 readily on the predetermined bending parts and since the stress applied to the electrical connections is small, then the connection reliability is improved.

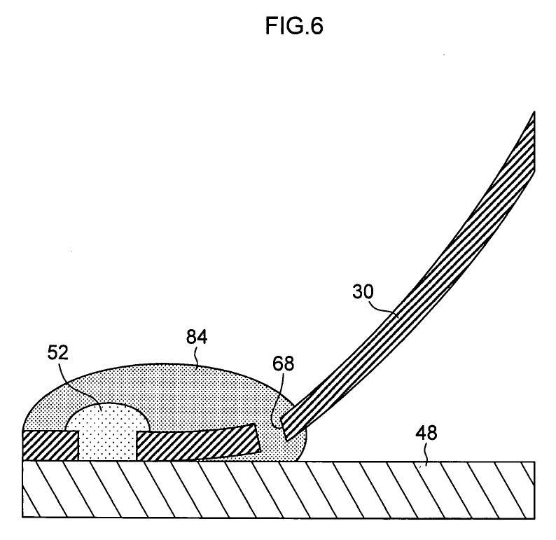

Moreover, as shown in FIG. 6, a desirable mode is one in which fixing resin 84, such as an adhesive material, is applied to the aforementioned connections, by means of an inkjet method or dispenser method, or the like. The fixing resin 84 may be a photo-curable resin, a thermo-curable epoxy resin, an acrylic resin, or the like.

When the connections are covered with the fixing resin 84, it is preferable that the fixing resin 84 is also filled into the bending perforations 68 in the vicinity of the connections. Thereby, the fixing resin 84 also reaches to the rear side of the flexible circuit board 30 through the perforations 68, and the vicinity of the bending part of the flexible circuit board 30 can be secured with the fixing resin 84. Thus, the bonding strength can be enhanced yet further by the resultant anchoring effect.

In the present embodiment, after applying the fixing resin 84 that has ultraviolet-curable properties, the applied fixing resin 84 is irradiated with ultraviolet light and cured, thereby securing the piezoelectric elements 22 (the connecting parts of the upper electrode films 48) to the flexible circuit board 30.

### Modified Embodiment 1

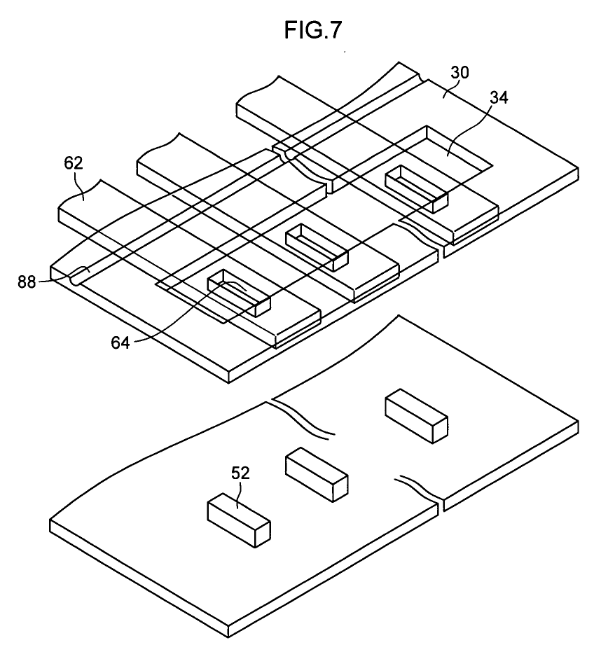

In the above-described embodiment, the bending perforations 68 are formed between the wires 62 of the flexible circuit board 30; however, it is also possible to form a groove or recess 88 on the bending line as shown in FIG. 7 instead of the perforations 68. In FIG. 7, the members that are the same as or similar to the members shown in FIG. 3 are denoted with the same reference numerals, and further explanation thereof is omitted here.

In the case where the bending perforations 68 are provided (see FIGS. 2 and 3), there are restrictions on the extent to which the density of the wiring can be raised, due to the need to ensure spaces for arranging the perforations 68 between the wires. On the other hand, in the case where the groove (recess) 88 is formed as shown in FIG. 7, a merit is obtained in that the wiring density can be raised further. The cross-sectional shape of the groove 88 is not limited to the semicircular arc shape shown in FIG. 7 and the shape, size, number and pitch of the grooves, and the like, are designed from the viewpoint of the bending angle, and the rigidity and elasticity, and the like that are to be achieved in the flexible circuit board 30.

### Modified Embodiment 2

In the above-described embodiment, the bending parts are arranged at two positions (A and B in FIG. 2); however, there are no particular restrictions on the positions of bending parts, the number of bending parts, and the like, and they may be designed in accordance with the actual composition of the apparatus.

Furthermore, it is also possible to adopt a mode in which the processed part of the perforations 68 and the processed part of the groove (recess) 88 are assembled together.

From the viewpoint of improving the bonding strength caused by the fixing resin 84 described with reference to FIG. 6, a desirable mode is one in which the perforations 68 also serve for the passage of the fixing resin 84 in the portion adjacent to the connecting part.

### Modified Embodiment 3

In the above-described embodiment, the wires 62 of the flexible circuit board 30 are electrically connected with the upper electrode films 48 of the piezoelectric elements 22 by spreading out the tip portions of the projections 52; however, instead of this mode, it is also possible to bond them by soldering or plating.

### Modified Embodiment 4

In the above-described embodiment, the flexible circuit board and the piezoelectric elements are connected in the liquid droplet ejection head, which is typically an inkjet head; however, the scope of application of the present invention is not limited to this and it can also be applied broadly to cases of connecting wires using a flexible circuit board, in a wide variety of electronic components.

### Aspects of the Present Invention

As has become evident from the detailed description of the embodiments of the present invention given above, the present specification includes disclosure of various technical ideas including various aspects of the invention described below.

The aspect 1 is directed to a connecting structure of a flexible circuit board and electronic components, comprising: the flexible circuit board having: a pattern of wires, holes passing through the flexible circuit board in a thickness direction of the wires at parts of the wires to which the electronic components are connected, and a weakened part arranged on a bending line in a bending part of the flexible circuit board on which the flexible circuit board bends when the wires are connected with the electronic components; and the electronic components respectively having projections on parts to which the wires are connected, wherein the wires are electrically connected with the electronic components in a state where the projections are inserted in the holes and the flexible circuit board bends on the weakened part.

According to the aspect 1 of the present invention, due to the interlocking structure of the holes, which are formed through the wires of the flexible circuit board, and the projections on the electronic components that are being connected, and due to the ease of bending created by the processing of the bending part in the flexible circuit board (the weakened part), the positional alignment of the wires is facilitated, detachment after bonding is not liable to occur and reliable electrical connections can be achieved. The connecting structure is particularly suitable for connection in sections where there is a difference in level (for instance, when creating electrical connections in the bottom of a groove).

The aspect 2 is directed to the connecting structure according to the aspect 1, wherein the weakened part has perforations which pass through the flexible circuit board and are arranged on the bending line.

The aspect 3 is directed to the connecting structure according to the aspect 2, wherein each of the perforations is arranged between the wires on the flexible circuit board.

If the perforations for bending are formed, then they are formed between the respective wires (namely, in the substrate of the flexible circuit board).

The aspect 4 is directed to the connecting structure according to the aspect 2, further comprising fixing resin which covers connections at which the projections have been inserted in the holes and the wires have been electrically connected with the electronic components, wherein at least one of the perforations is arranged nearby each of the connections and filled with the fixing resin.

By making the fixing resin enter into the perforations for bending, it is possible to increase the bonding strength further.

The aspect 5 is directed to the connecting structure according to the aspect 1, wherein the weakened part has a groove arranged on the bending line.

The aspect 6 is directed to the connecting structure according to the aspect 1, wherein the flexible circuit board has a plurality of the bending parts which respectively have a plurality of the weakened parts.

The aspect 7 is directed to the connecting structure according to the aspect 1, wherein in a state where the projections are inserted in the holes, tip portions of the projections protruding from the holes are spread out and the projections are thereby secured to the wires.

The aspect 8 is directed to a method of connecting electronic components and a flexible circuit board having a pattern of wires, the method comprising the steps of: forming holes passing through the flexible circuit board in a thickness direction of the wires at parts of the wires to which the electronic components are connected; forming a weakened part arranged on a bending line in a bending part of the flexible circuit board on which the flexible circuit board bends when the wires are connected with the electronic components; forming projections on parts of the electronic components to which the wires are connected; and connecting the electronic components and the flexible circuit board by inserting the projections into the holes to electrically connect the wires with the electronic components and bending the flexible circuit board on the weakened part.

According to the connecting method of the aspect 8 of the present invention, positional alignment of the flexible circuit board is easy and reliable electrical connections which prevent detachment after bonding can be achieved.

The aspect 9 is directed to the connecting method according to the aspect 8, wherein the step of forming the weakened part includes the step of forming perforations which pass through the flexible circuit board and are arranged on the bending line.

The aspect 10 is directed to the connecting method according to the aspect 9, wherein each of the perforations is arranged between the wires on the flexible circuit board in the step of forming the perforations.

The aspect 11 is directed to the connecting method according to the aspect 9, further comprising the step of covering, with fixing resin, connections at which the projections have been inserted in the holes and the wires have been electrically connected with the electronic components in the step of connecting the electronic components and the flexible circuit board, wherein at least one of the perforations is arranged nearby each of the connections in the step of forming the perforations, and is filled with the fixing resin in the step of covering the connection with the fixing resin.

The aspect 12 is directed to the connecting method according to the aspect 8, wherein the step of forming the weakened part includes the step of forming a groove arranged on the bending line.

The aspect 13 is directed to the connecting method according to the aspect 8, wherein: the flexible circuit board has a plurality of the bending parts; and a plurality of the weakened parts are respectively formed in the bending parts in the step of forming the weakened part.

The aspect 14 is directed to the connecting method according to the aspect 8, wherein the step of connecting the electronic components and the flexible circuit board includes the step of spreading out tip portions of the projections that protrude from the holes to thereby secure the projections to the wires.

The aspect 15 is directed to a liquid droplet ejection head, comprising the connecting structure according to the aspect 1.

The aspect 16 is directed to a method of manufacturing a liquid droplet ejection head, comprising the method according to the aspect 8.

One compositional embodiment of a liquid droplet ejection head according to the present invention is a full line type head in which a plurality of nozzles are arranged through a length corresponding to the full width of the ejection receiving medium. In this case, a mode may be adopted in which a plurality of relatively short recording head modules having nozzles rows which do not reach a length corresponding to the full width of the ejection receiving medium are combined and joined together, thereby forming nozzle rows of a length that correspond to the full width of the ejection receiving medium.

A full line type head is usually disposed in a direction that is perpendicular to the feed direction (conveyance direction) of the ejection receiving medium, but a mode may also be adopted in which the head is disposed along an oblique direction that forms a prescribed angle with respect to the direction perpendicular to the conveyance direction.

The conveyance device for causing the ejection receiving medium and the liquid droplet ejection head to move relatively to each other may include a mode where the ejection receiving medium is conveyed with respect to a stationary (fixed) head, or a mode where a head is moved with respect to a stationary ejection receiving medium, or a mode where both the head and the ejection receiving medium are moved.

The “ejection receiving medium” is a medium which receives the deposition of liquid droplets ejected from the nozzles (ejection ports) of a liquid droplet ejection head, and this term includes a print medium, image forming medium, recording medium, image receiving medium, intermediate transfer body, or a conveyance device such as a conveyance belt of a recording medium, or the like, in an inkjet printer. There are no particular restrictions on the shape or material of the medium, which may be various types of media, irrespective of material and size, such as continuous paper, cut paper, sealed paper, resin sheets, such as OHP sheets, film, cloth, a printed circuit substrate on which a wiring pattern, or the like, is formed, a rubber sheet, a metal sheet, or the like.

When forming color images by using an inkjet head, it is possible to provide recording heads for respective colors of a plurality of colored inks (recording liquids), or it is possible to eject inks of a plurality of colors, from one print head.

Furthermore, the invention is not limited to an inkjet recording apparatus using a page-wide full line type head having a nozzle row of a length corresponding to the entire width of the recording medium, and the present invention can also be applied to an inkjet recording apparatus which performs image recording by means of a plurality of head scanning actions which move a short recording head, such as a serial head (shuttle scanning head), or the like.

Furthermore, the image forming apparatus which comprises the liquid droplet ejection head is not restricted to a so-called graphic printing application for printing photographic prints or posters, but rather also encompasses industrial apparatuses which are able to form patterns that may be perceived as images, such as resist printing apparatuses, wire printing apparatuses for electronic circuit substrates, ultra-fine structure forming apparatuses, etc., which use inkjet technology.

It should be understood, however, that there is no intention to limit the invention to the specific forms disclosed, but on the contrary, the invention is to cover all modifications, alternate constructions and equivalents falling within the spirit and scope of the invention as expressed in the appended claims.

1. A connecting structure of a flexible circuit board and electronic components, comprising:
the flexible circuit board having: a pattern of wires, holes passing through the flexible circuit board in a thickness direction of the wires at parts of the wires to which the electronic components are connected, and a weakened part arranged on a bending line in a bending part of the flexible circuit board on which the flexible circuit board bends when the wires are connected with the electronic components; and
the electronic components respectively having projections on parts to which the wires are connected,
wherein the wires are electrically connected with the electronic components in a state where the projections are inserted in the holes and the flexible circuit board bends on the weakened part.

2. The connecting structure as defined in claim 1, wherein the weakened part has perforations which pass through the flexible circuit board and are arranged on the bending line.

3. The connecting structure as defined in claim 2, wherein each of the perforations is arranged between the wires on the flexible circuit board.

4. The connecting structure as defined in claim 2, further comprising fixing resin which covers connections at which the projections have been inserted in the holes and the wires have been electrically connected with the electronic components,
wherein at least one of the perforations is arranged nearby each of the connections and filled with the fixing resin.

5. The connecting structure as defined in claim 1, wherein the weakened part has a groove arranged on the bending line.

6. The connecting structure as defined in claim 1, wherein the flexible circuit board has a plurality of the bending parts which respectively have a plurality of the weakened parts.

7. The connecting structure as defined in claim 1, wherein in a state where the projections are inserted in the holes, tip portions of the projections protruding from the holes are spread out and the projections are thereby secured to the wires.

8. A method of connecting electronic components and a flexible circuit board having a pattern of wires, the method comprising the steps of:
forming holes passing through the flexible circuit board in a thickness direction of the wires at parts of the wires to which the electronic components are connected;
forming a weakened part arranged on a bending line in a bending part of the flexible circuit board on which the flexible circuit board bends when the wires are connected with the electronic components;
forming projections on parts of the electronic components to which the wires are connected; and
connecting the electronic components and the flexible circuit board by inserting the projections into the holes to electrically connect the wires with the electronic components and bending the flexible circuit board on the weakened part.

9. The method as defined in claim 8, wherein the step of forming the weakened part includes the step of forming perforations which pass through the flexible circuit board and are arranged on the bending line.

10. The method as defined in claim 9, wherein each of the perforations is arranged between the wires on the flexible circuit board in the step of forming the perforations.

11. The method as defined in claim 9, further comprising the step of covering, with fixing resin, connections at which the projections have been inserted in the holes and the wires have been electrically connected with the electronic components in the step of connecting the electronic components and the flexible circuit board,
wherein at least one of the perforations is arranged nearby each of the connections in the step of forming the perforations, and is filled with the fixing resin in the step of covering the connection with the fixing resin.

12. The method as defined in claim 8, wherein the step of forming the weakened part includes the step of forming a groove arranged on the bending line.

13. The method as defined in claim 8, wherein:
the flexible circuit board has a plurality of the bending parts; and
a plurality of the weakened parts are respectively formed in the bending parts in the step of forming the weakened part.

14. The method as defined in claim 8, wherein the step of connecting the electronic components and the flexible circuit board includes the step of spreading out tip portions of the projections that protrude from the holes to thereby secure the projections to the wires.

15. A liquid droplet ejection head, comprising:
a connecting structure including:
a flexible circuit board having a pattern of wires, holes passing through the flexible circuit board in a thickness direction of the wires at parts of the wires to which the electronic components are connected, and a weakened part arranged on a bending line in a bending part of the flexible circuit board on which the flexible circuit board bends when the wires are connected with a plurality of electronic components:
wherein said electronic components respectively have projections on parts to which the wires are connected; and
wherein the wires are electrically connected with said electronic components in a state where the projections are inserted in the holes and the flexible circuit board and are arranged on the bending line.

16. A method of manufacturing a liquid droplet ejection head, comprising:
forming holes passing through a flexible circuit board in a thickness direction of a plurality of wires at parts of the wires to which a plurality of electronic components are connected;
forming a weakened part arranged on a bending line in a bending part of the flexible circuit board on which the flexible circuit board bends when the wires are connected with the electronic components;
forming projections on parts of the electronic components to which the wires are connected; and
connecting the electronic components and the flexible circuit board by inserting the projections into the holes to electrically connect the wires with the electronic components and bending the flexible circuit board on the weakened part.
